(19) United States
(12) Patent Application Publication
(10) Pub. No.: US 2005/0130393 A1
(43) Pub. Date: Jun. 16, 2005

(54) Method for improving the quality of heterostructure

(76) Inventors: Beryl Blondeau, La Tronche (FR); Ian Cayrefourcq, St. Nazaire les Eymes (FR); Eric Guiot, Goncelin (FR); Thibaut Maurice, Grenoble (FR); Hubert Moriceau, Saint Egreve (FR)

Correspondence Address: WINSTON & STRAWN LLP, 1700 K STREET, N.W., WASHINGTON, DC, 20006, US

(21) Appl. No.: 10/840,581

(22) Filed: May 5, 2004

(30) Foreign Application Priority Data
Dec. 10, 2003 (EP) 03 293 102.4

(51) Int. Cl. C30B 1/00; H01L 21/20; H01L 21/36

(52) U.S. Cl. 438/479

(57) ABSTRACT

A method for improving the quality of a heterostructure that includes at least two layers of material that have different thermal expansion coefficients is described. The method includes applying a cap layer to the exposed surface of at least one of the layers. The cap layer is made of a material and has a thickness sufficient to reduce defects in at least one of the two layers during subsequent thermal treatment of the heterostructure. The present technique is a reliable and effective method for improving the quality of a heterostructure.

### BACKGROUND ART

The present invention relates to a method for improving the quality of a heterostructure. The heterostructure consists of at least two material layers which are connected together, each material having a different thermal expansion coefficient. The method includes applying a cap layer to the heterostructure, and may further include an annealing step.

Heterostructures can be composed of silicon-on-quartz (SOQ), SiGe-on-silicon, germanium-on-silicon, silicon carbide-on-silicon or Group III-V-semiconductors-on-silicon structures. Heterostructures which have a thin layer of one material bonded onto a substrate of another material are especially attractive for micro-electronics and opto-electronics applications. An additional layer such as insulator layer can be inserted between the thin layer and the substrate. Heterostructures may be formed by using a layer transfer technique, such as by detaching a hetero-bonded structure from a substrate using a SMART-CUT® process. The surface of such heterostructures resulting from the use of such a layer transfer techniques is relatively rough, so that it is typically necessary to use a finishing process on the surface after detachment. In addition, it is usually necessary to improve the bonding interface and to remove implantation defects.

One approach used to finish a surface of a SOI structure is described in published International Application No. WO 01/15215 A1. In a first step, the heterostructure is annealed using a rapid thermal annealing process having a maximum temperature of about 1200° C. to 1230° C. resulting in decreased roughness of the surface and improved bonding strength. A chemical-mechanical polishing step may additionally be used to further lower the roughness value of the surface. When such a method is used to fabricate heterostructures, process-induced defects, such as grid defects, are formed when temperatures over a few hundred degrees Centigrade (° C.) are used. When temperatures below about a few hundred ° C. are used, the result is insufficient bonding strength of the layers. Grids, slip lines or other crystal defects which are the size of a few atomic planes and are formed at the surface and/or at a bonding interface of an overheated heterostructure, cause the structure to be unusable for most tasks HF-defects are defects that can be observed by using a HF-solution, which makes the defects visible. HF-defects are on the order of about 0.1 to 0.5 microns.

The defects described above may result from and/or are amplified by the thermally induced stress of the heterostructure caused by the difference in the thermal expansion coefficients of the materials that are present in the heterostructure.

### SUMMARY OF THE INVENTION

The present invention now provides a reliable and more effective method for improving the quality of a heterostructure that includes at least two layers of material that have different thermal expansion coefficients. This is achieved by a method which comprises applying a cap layer to the exposed surface of at least one of the layers, with the cap layer being made of a material and having a thickness sufficient to reduce defects in at least one of the two layers during subsequent thermal treatment of the heterostructure.

The heterostructure preferably includes at least one useful layer and a supporting substrate, and the subsequent thermal treatment includes annealing the heterostructure.

Experiments have shown that the presence of a cap layer results in fewer thermally-induced defects. The capacity to use high temperatures in the annealing step makes it possible to obtain high quality heterostructures with an increased stability due to a high bonding force between the materials of the heterostructure and/or to reduce defect density of the heterostructure. Using a cap layer applied to SOQ-wafers reduces HF defect density under thermal treatment.

In a special embodiment of the present invention, the cap layer is brought onto a top surface of the heterostructure formed by a layer transfer technique, especially by implantation, direct bonding and detachment. By this method, the cap layer can be used to improve the quality of the heterostructure, particularly the defect density of its top layer. During thermal treatment, the cap layer protects the surface of the top layer, so that a chemical reaction such as a thermal oxidation or another influence of the annealing atmosphere on the top layer can be reduced.

In a favorable example of the invention, at least one silicon dioxide layer and/or at least one silicon nitride layer is brought onto the heterostructure as the cap layer. The use of silicon dioxide and/or silicon nitride allows an easy and effective protection of the heterostructure, to reduce a formation of defects by the annealing step.

In a preferable embodiment of the invention, the cap layer is brought onto the heterostructure using a film deposition technique selected from a group comprising plasma-enhanced chemical vapor deposition, magnetron sputtering and ion-assisted electron beam separation. These deposition techniques are very well-suited to form a cap layer on the heterostructure in an easy but defined way.

It is furthermore advantageous when the annealing step is performed at a temperature of about 500° C. to about 1200° C. This method has the advantage that through a temperature treatment in this temperature region a very high quality of the crystalline and/or the surface characteristics of the heterostructure can be obtained. Furthermore, the bonding force between the materials of the heterostructure can be increased.

According to another beneficial embodiment of the invention, the cap layer is removed after the annealing step. In this manner, the heterostructure can be uncovered but maintains its improved quality.

In a yet further favorable variant of the invention, the cap layer is removed by at least one technique selected from a group comprising chemical-mechanical polishing, dry etching or wet etching. By these techniques, the cap layer can be removed efficiently with little or no influence on the quality of the uncovered heterostructure.

At least one layer of the heterostructure is preferably are made of silicon, germanium, silicon carbide, silicon dioxide, fused silica, or a Group III-V-semiconductor material. In an implementation, at least one layer comprises a substrate and a deposited layer made of at least one of SiGe, Ge, GaN, or AsGa.

In yet another advantageous embodiment of the invention, a surface of the heterostructure is polished before the cap layer is brought onto said surface. The polishing step results in a flat surface of the heterostructure wherein slight eventual polishing defects of the surface can be reduced with less risk of a thermal oxidation of the polished surface, due to the protecting cap layer on that surface.

In a specific example of the invention, the cap layer is composed of at least two sub-layers, especially a SiO₂ and a Si₃N₄ layer. The materials and properties of the sub-layers can be adjusted to the desired effect to be obtained. SiO₂ and Si₃N₄ layers are specifically advantageous for the method and help to reduce HF defect density under thermal treatment.

### BRIEF DESCRIPTION OF THE DRAWINGS

Other aspects, purposes and advantages of the invention will become clear after reading the following detailed description with reference to the attached drawings, in which:

FIG. 1 to FIG. 4 illustrate an example for providing a heterostructure according to an embodiment of the present invention;

FIG. 5 to FIG. 6 illustrate examples of heterostructures that can be used in embodiments of the present invention;

FIG. 7 to FIG. 10 are examples of heterostructures that include at least one cap layer according to the present invention;

FIG. 11 illustrates an annealing step according to an embodiment of the present invention; and

FIG. 12 to FIG. 13 illustrate heterostructures that result from using methods according to embodiments of the present invention.

### DETAILED DESCRIPTION OF THE PREFERRED EMBODIMENTS

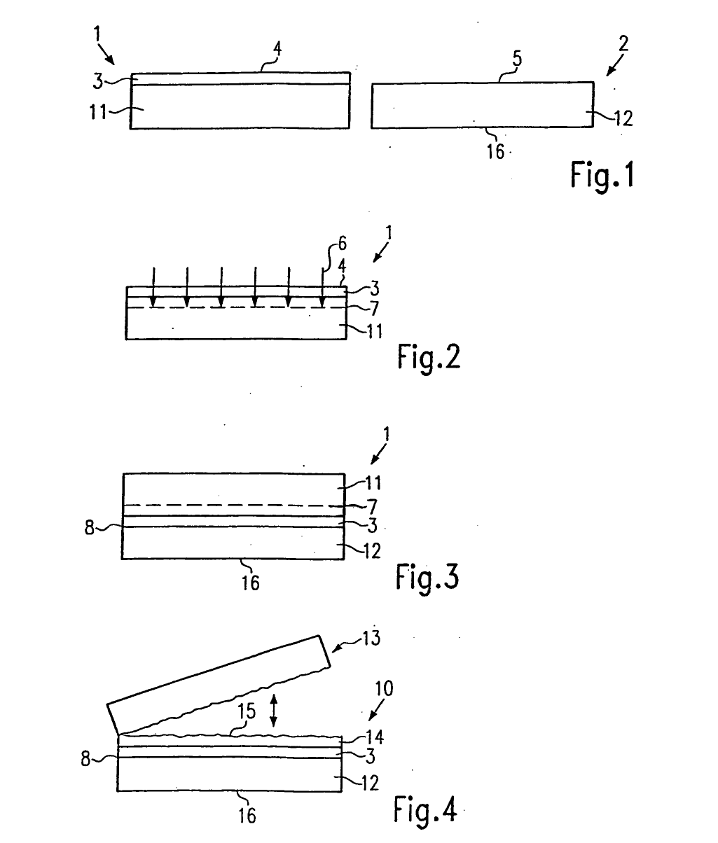

FIGS. 1 through 4 schematically show an exemplary process for producing a heterostructure 10 according to a preferred embodiment of the invention. Referring to FIG. 1, a first wafer 1 and a second wafer 2 are provided. Wafer 1 comprises a substrate 11 composed of a material that is different from the material of the substrate 12 of wafer 2. In particular, the substrates 11 and 12 are made of materials with different thermal expansion coefficients. The material of the substrates 11 and 12 can be, for example, silicon, germanium, silicon carbide, silicon dioxide, fused silica, Group III-V-semiconductors or other materials which are suitable for forming heterostructures. For instance, wafer 1 may be composed of a support substrate on which one or more layers of semiconductor material (SiGe, Ge, GaN, AsGa) are deposited. Although it may not be necessary, the wafer 1 shown in FIG. 1 includes an auxiliary layer 3 of a material such as silicon dioxide on top of the substrate 11. In a subsequent step, the surface 4 of wafer 1 and the surface 5 of wafer 2 are brought together.

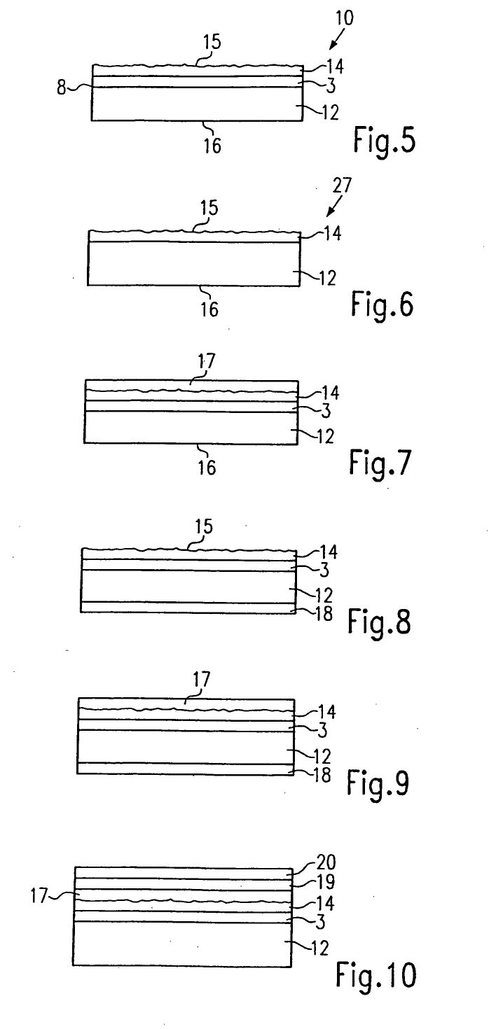

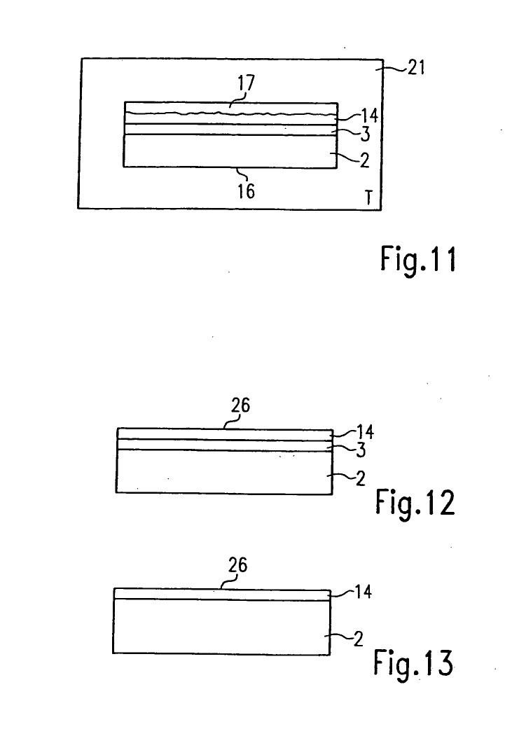

As shown in FIG. 2, wafer 1 is implanted with species 6 such as hydrogen ions. The species pass through the surface 4 and the auxiliary layer 3 to concentrate at a certain depth within the substrate 11 to form a pre-determined weakened area 7 at or near a level of maximum concentration of species. Referring to FIG. 3, the implanted wafer 1 shown in FIG. 2 and the wafer 2 of FIG. 1 are bonded together at their surfaces 4, 5. This bonding step results in a heterostructure 9 with a bonding interface 8. In the ensuing step shown in FIG. 4, the bonded heterostructure 9 of FIG. 3 is split into two structures 10 and 13 along the pre-determined weakened area 7 shown in FIG. 3. The first structure 10 is a heterostructure consisting of the thick substrate 12 of the former wafer 2, the auxiliary layer 3 and a transferred layer 14 of the substrate 11 from the wafer 1. The transferred layer is a useful layer or a thin top layer 14 of the heterostructure 10, and the useful layer 14 has a thermal expansion coefficient that is different from that of the substrate 12. The useful layer 14 forms the active part of the heterostructure, and because it has been detached the useful layer 14 has a relatively rough surface 15. This surface roughness is undesirable for most applications of the heterostructure 10. It is also noted that the heterostructure 10 has a back side 16 which corresponds to the back side 16 of the original wafer 2.

FIG. 5 illustrates the heterostructure 10 of FIG. 4 after it has been separated from the residual part 13. Another embodiment of a heterostructure 27 is shown in FIG. 6 that can be used according to the present technique. This embodiment of a heterostructure 27 consists of a substrate 12 and a top layer 14 having a surface 15 of increased roughness. In other embodiments of the invention, heterostructures may include one or more additional layers in accordance with the intended uses of such heterostructures. Further, it is not absolutely necessary for the heterostructures 10, 27 to be formed by a layer transfer technique such as that described above and shown in FIGS. 1 through 4. The heterostructures 10, 27 can also be formed by another layer transfer technique, or by a layer growth process, or a deposition technique, in which at least two materials with different thermal expansion coefficients are connected together. The layers of different material may be adhered together by any suitable process including, but not limited to, bonding, physical and/or chemical processes, gluing or welding. The surface 15 of the useful layer 14 that has been detached from the wafer 1 can be polished to decrease the roughness of the surface 15. The polished surface 15 can have slight polishing defects.

The heterostructure 10, 27 can be a silicon-on-quartz(SOQ) structure, a SiGe-on-Silicon structure, a Ge-on-Silicon structure, a SiC-on-Silicon structure, a Group III-V-semiconductor-on-silicon structure or another material compound. In the embodiment shown in FIG. 6, the heterostructure 27 is a SOQ-structure consisting of a silicon layer 14 that is about 200 nm thick on a substrate 12 of fused silica, made by using a SMART-CUT® process. An additional layer, such as an insulator layer, can be inserted between the thin top layer and the substrate.

Stress is present in this heterostructure during thermal treatments because of the different thermal expansion coefficients of the materials therein. The stress is particularly localized inside the top layer 14 and/or at the bonding interface 8. With reference to the heterostructure 27, the silicon useful layer 14 is in a compressive state at the interface 8 due to its thermal coefficient mismatch with the substrate 12 of fused silica. The stress appears and increases when higher temperatures are applied to the heterostructure 10 or 27. If a certain stress limit is exceeded, defects like HF defects can form. The HF defect density of the example SOQ-structure 27 having a 200 nm thick silicon useful layer 14, after thermal treatment at about 950° C., is between about 24 cm⁻² and 40 cm⁻². To prevent such undesirable results, the heterostructure 10 of FIG. 5 is covered by a cap layer 17 as shown in FIG. 7. The cap layer is deposited directly onto the rough surface 15 of the useful top layer 14 that has been formed due to the detachment step of a layer transfer process. The material and the thickness of the cap layer 17 are chosen, for example, according to the thickness relationship and the difference of thermal expansion coefficients of the materials that comprise the heterostructure 10 in a manner sufficient to prevent defects. Thus, the material of the cap layer 17 and the thickness of it are chosen in a manner sufficient to reduce defects in the heterostructure that could occur after an annealing step.

It is noted that the cap layer may be deposited on the back side 16 of the heterostructure, either alone or in addition to the cap layer formed on the surface 15. Applying the cap layer to the back side may simplify the process, or may compensate for the stress imparted on the heterostructure the cap layer 17 formed on the surface 15 of the top or useful layer 14.

FIG. 10 shows yet another embodiment of the present invention, in which several cap layers 17, 19, and 20 are provide on the top or useful layer 14 of the heterostructure 10. In a preferred embodiment, at least the cap layer 19 is composed of a material that is different from that of the other cap layers 17 and 20. In yet another preferred embodiment, the cap layer(s) 17, 18, 19, and 20 shown in FIGS. 7 through 10 are made of silicon dioxide and/or silicon nitride and/or oxynitrides (SiON). For example, the cap layer(s) may consist of a layer sequence of about 50 nm SiO₂ and about 50 nm Si₃N₄, of about 100 nm SiO₂ and about 50 nm Si₃N₄, of about 100 nm SiO₂, of about 50 nm Si₃N₄ and 100 nm SiO₂ or of other favorable layer sequences, including a single layer such as a 50 nm thick Si₃N₄ layer or a 1000 nm thick SiO₂ layer.

The cap layers 17, 18, 19, 20 can be deposited by using a plasma-enhanced chemical vapor deposition (PE-CVD) process performed in a reactor at temperatures up to about 400° C. The thickness and the characteristics of a layer deposited in this way can be adjusted via the RF power of the plasma in the reactor, the pressure of the gases used, such as SiH₄ and NH₃, the proportion of the gases used, and the deposition temperature and time duration. When PE-CVD deposition is used, the frequency of the RF power can be varied to influence the deposition and the characteristics of the deposited layer. Typically, the RF frequency for a high-frequency domain is about 13.56 MHz, and can be in a mid-frequency range of about 1 to 4 MHz, and in a low-frequency range of about 80 and 500 kHz. Furthermore, the bias current at the back face of the heterostructure can be used as a parameter in a PE-CVD process.

The following parameters may beneficially be used to conduct a PE-CVD deposition process of a SiO₂ cap layer with a thickness of about 50nm. The temperature of the plasma can be adjusted to be about 400° C. The thickness of the deposited layer is mainly controlled by the deposition time duration, which can be a few seconds. Further favorable parameters of a SiO₂ deposition that may be used include an RF power of about 200W and a chamber pressure of about 2.5 Torr. The gases used are typically SiH₄ and N₂O.

The following are typical parameters for a PE-CVD deposition of a Si₃N₄-cap layer with a thickness of about 50 nm. The temperature of the plasma should be about 400° C. A few seconds of deposition time are sufficient. An RF power of about 625W and a chamber pressure of about 5 Torr are advantageous. Gases such as SiH₄, N₂ and NH₃ may be used.

The characteristics of the deposited layer are collectively controlled by the parameters used during the deposition process. Such parameters may include the kind of deposition, the material used, the pressure, the proportion, the dilution and the nature of the gases used, the applied temperatures, the bias current, and the RF frequency.

In a further embodiment of the invention, any of the cap layers 17, 18, 19, and 20 is deposited by using a physical vapor deposition process, like magnetron sputtering. When this method is utilized, the thickness and the characteristics of the deposited material are controlled by adjusting the RF power of the plasma, the nature, the pressure and the proportion of the gases used, such as SiH₄ and NH₃, and also by adjusting the bias current and the temperature of the substrate.

In another variant of the invention, any of the cap layers 17, 18, 19, 20 can be formed by a UHV ion-assisted electron beam deposition process. In this method, the ion energy and the substrate temperature are controlled to obtain a certain layer thickness and certain characteristics of the deposited layer. The cap layer 17, 18, 19, 20 can act as a diffusion barrier to prevent diffusion of reactants of the annealing atmosphere into the heterostructure 10, 27 and in particular into the thin top layer or useful layer 14.

FIG. 11 illustrates a cap layer-covered heterostructure, such as a structure like that shown in FIGS. 7 through 10, being annealed in a furnace 21. It is noted that, instead of annealing in a furnace, any other thermal treatment can be applied to heat such a cap layer-covered heterostructure. For example a photonic treatment, rapid thermal processing (RTP), a laser treatment, or a microwave treatment can be applied.

Thermal treatment advantageously occurs in a temperature region from about 500° C. to about 1200° C., typically over a period of between about 1 to 4 hours. Tests have been performed at 950° C., 1020° C. and 1100° C., and the results show very low HF defect densities of capped SOQ-structures after annealing. The results showed HF defect densities to be in the range of about 5 down to about 0.3 HF defects per cm². No defects were observed for thermal treatments in a temperature region of about 750° C. to about 1000° C. Advantageous gas environments for thermal treatment can include pure Ar or ArO₂ and O₂. Thus, use of high temperature annealing according to the present method does not degrade the crystal quality and/or the surface quality of the useful layer 14.

As discussed above, the surface 15 may be polished before depositing one or more of the cap layers 17, 19, and 20 on top of it. In such heterostructures, slight polishing defects induced by the polishing step are reduced by the thermal annealing step. When at least one of the cap layers 17, 19, and 20 is applied onto the top layer or useful layer 14, it should be noted that the useful layer 14 is protected by such a cap layer. Consequently, the useful layer 14 is protected from any thermal oxidation, or other chemical reaction, or a physical influence on the surface induced by the atmosphere. Moreover, the high temperatures used in the annealing step enhance the bonding force between the top layer or useful layer 14 and the substrate 12.

As shown in FIGS. 12 and 13, after the annealing step shown in FIG. 11 the at least one cap layer 17, 18, 19, and/or 20 is removed. Removal can be accomplished by using a chemical-mechanical polishing technique, or a dry etching process, or a wet etching technique. Such methods can effectively remove the at least one cap layer with little or no effect on the quality of the heterostructure. As shown in particular in FIGS. 12 and 13, the resulting surface 26 of the useful layer 14 has an improved surface roughness and is free of thermal-induced defects like grids. In the heterostructures of FIGS. 12 and 13, the useful layer 14 is uncovered on top of the respective structures, so that these heterostructures are ready for further processing.

1. A method for improving the quality of a heterostructure that includes at least two layers of material that have different thermal expansion coefficients, which comprises: applying a cap layer to the exposed surface of at least one of the layers, the cap layer being made of a material and having a thickness sufficient to reduce defects in at least one of the two layers during subsequent thermal treatment of the heterostructure.

2. The method of claim 1, wherein the heterostructure includes at least one useful layer and a supporting substrate, and wherein the subsequent thermal treatment includes annealing the heterostructure.

3. The method of claim 2, wherein annealing occurs at a temperature of about 500° C. to about 1200° C.

4. The method of claim 2, further comprising removing the at least one cap layer after the subsequent thermal treatment.

5. The method of claim 4, wherein the at least one cap layer is removed by chemical-mechanical polishing, dry etching or wet etching.

6. The method of claim 1, wherein the heterostructure is formed by using a layer transfer technique.

7. The method of claim 1, which further comprises polishing at least one of the exposed surfaces of the layers before applying the at least one cap layer.

8. The method of claim 1, which further comprises applying the at least one cap layer onto the heterostructure by a film deposition technique.

9. The method of claim 8, wherein the film deposition technique is at least one of plasma-enhanced chemical wafer deposition, magnetron sputtering, or ion-assisted electron beam deposition.

10. The method of claim 1, wherein at least one layer is made of silicon, germanium, silicon carbide, silicon dioxide, fused silica, or a Group III-V-semiconductor material.

11. The method of claim 1, wherein at least one layer comprises a substrate and a deposited layer made of at least one of SiGe, Ge, GaN, or AsGa.

12. The method of claim 1, wherein the at least one cap layer is composed of at least one of silicon dioxide or silicon nitride.

13. The method of claim 1, wherein the at least one cap layer is composed of at least two sub-layers.

14. The method of claim 11, wherein at least a first sub-layer is composed of SiO₂ and a second sub-layer is composed of Si₃N₄.
